(19) United States
(12) Patent Application Publication
(10) Pub. No.: US 2026/0088529 A1
(43) Pub. Date: Mar. 26, 2026

(54) CONNECTOR ASSEMBLY FOR ELECTRIC CABLES AND ELECTRIC CONNECTOR

(71) Applicant: TE Connectivity India Private Limited, Bangalore (IN)

(72) Inventors: Vinay UTTARKAR, Bangalore (IN); Yogeshchandra KARIYAPPA, Bangalore (IN)

(21) Appl. No.: 19/335,698

(22) Filed: Sep. 22, 2025

(30) Foreign Application Priority Data
Sep. 24, 2024 (IN) 202441071997

(51) Int. Cl. H01R 9/22; H01R 13/02; H01R 13/436; H05K 7/20

(52) U.S. Cl. CPC H01R 9/226; H01R 9/223; H01R 13/025; H01R 13/436; H05K 7/20127

(57) ABSTRACT

A connector assembly for electric cables having a predetermined wire gauge to be mated with a mating connector along a mating direction includes a plurality of terminals arranged on a common terminal plane. The common terminal plane extends parallel to the mating direction. Each of the terminals is configured to be connected to at least one wire. The distances between each of the plurality of terminals in a pitch direction is smaller than the predetermined wire gauge. An electric connector including the connector assembly further includes a mating connector having a plurality of mating contacts with a mating pitch that is equal to the distance of the terminals of the connector assembly.

### CROSS REFERENCE TO RELATED APPLICATIONS

This application claims the benefit of IN Application No. 202441071997, filed 24, Sep. 2024 , the subject matter of which is herein incorporated by reference in its entirety.

### BACKGROUND OF THE INVENTION

The subject matter herein relates to a connector assembly for electric cables and an electric connector with the connector assembly and/or a mating connector.

There is a trend in electrical connectors towards miniaturization, as a smaller connector leaves space for other devices or allows the device in which the connector is used to be smaller. At the same time, there is often a requirement for the connectors, as they become smaller, to transmit ever greater currents. The transmission of larger currents requires an increased diameter of the wires, also termed “wire gauge”, connected to the connector. The necessity of providing increased wire gauges for larger currents conflicts with the miniaturization of the connectors.

There is therefore a need to provide an improved miniaturized connector which allows for the transmission of high currents.

### BRIEF DESCRIPTION OF THE INVENTION

In one embodiment, a connector assembly is provided for electric cables having a predetermined wire gauge to be mated with a mating connector along a mating direction comprising a plurality of terminals that is arranged on a common terminal plane, the common terminal plane extending parallel to the mating direction wherein each of the terminals is configured to be connected to at least one wire, the distances between each of the plurality of terminals in a pitch direction being smaller than the predetermined wire gauge.

In another embodiment, an electrical connector is provided comprising a connector assembly and/or a mating connector comprising a plurality of mating contacts with a mating pitch that is equal to the distance of the terminals of the connector assembly.

The above solutions are advantageous because it allows for a compact design while keeping the user and components safe by preventing short circuits effectively. The connector assembly and the electrical connector are easy to handle and to assemble.

The distance between the terminals of the plurality of terminals is also termed pitch of the terminals or the plurality of terminals. The pitch usually defines the distance between a center point of one terminal to the center point of an adjacent terminal along the pitch direction of the connector assembly. The pitch direction may extend perpendicular to the mating direction. The mating direction is defined as the direction along which the connector and its mating connector are joined.

The pitch is crucial for the size of the connector. The arrangement of the terminals in the common terminal plane and providing having a small pitch allows a flat and small connector to be provided. Providing a connector where the pitch is smaller than the wire diameter allows for the usage of larger wires for larger currents.

It is to be noted that a connector is configured to be used only with specific predetermined wire gauges that are e.g. determined in the manual. These predetermined wire gauges are thus an inherent feature of a connector. Using other than the specified wire gauges may not be considered a proper use of the connector.

The subject matter can be further improved by the following embodiments which are advantageous in themselves and which can be arbitrarily and independently combined with one another.

To hold, house or carry the plurality of terminals that can be inserted along the mating direction, the connector assembly may comprise a housing with a plurality of terminal receptacles.

The plurality of terminal receptacles may be arranged adjacent to each other along the pitch direction and configured to receive one terminal each. Each terminal receptacle may extend continuously or uninterruptedly in the mating direction.

The housing may have a prismatic shape and may have a shape resembling a cuboid. The housing may comprise a step-like extension extending from a face of the housing along the mating direction. The step-like extension may comprise a smaller height than the rest of the housing along a height direction. The height direction may be perpendicular to both the pitch direction and the mating direction. The pitch direction may thus be perpendicular to both the height direction and the mating direction. The mating direction may be perpendicular to both the height direction and the pitch direction.

The housing may comprise walls that separate each of the plurality of terminal receptacles from one other. The housing and/or the walls may be made from electrically insulating material like plastic to separate the terminals from one another, once the terminals are inserted into the terminal receptacles.

Each terminal of the plurality of terminals may be received in a different terminal receptacle of the plurality of terminal receptacles. This ensures a good electric insulation of the terminals in case of high currents.

Each terminal of the plurality of terminals may comprise two terminal plates. The terminal plates may be arranged parallel to one another within a terminal receptacle of the plurality of terminal receptacles. Using two terminal plates increases the conductive cross-section of the terminal and reduces resistance. High currents thus generate less heat.

The distance between the terminal plates, especially along the pitch direction, may be smaller than the predetermined wire gauge. This contributes to a compact design.

The terminal plates may extend parallel to the mating direction and/or an insertion direction, especially their common terminal plane may extend parallel to the mating direction. The insertion direction can be defined as the direction from which the terminals may be inserted into the terminal receptacles. The insertion direction may be the same as the mating direction. The terminal plates or their common plane may extend perpendicular to the pitch direction along the insertion direction or mating direction. These measures lead to a design which is easy to manufacture and assemble.

The terminal plates may be aligned in such a way that the two terminal plates maintain a constant distance from one other, for example, along the pitch direction, in particular across their entire area or surface. The terminal plates may be facing each other and be oriented in the same direction. With at least one of their flat surfaces each, both terminal plates may face a direction perpendicular to the mating direction, for example, the pitch direction.

Two terminal plates may be located opposite one another along a pitch direction in one terminal receptacle. The terminal plates may cover the side walls of a terminal receptacle in the pitch direction.

A height of a terminal and/or a terminal plate may be determined along the height direction. The plurality of terminals may all comprise terminal plates with the same height along the height direction. In another embodiment, the height of the terminal plates may vary along the mating direction or insertion direction, which may be combined, for example, with the embodiment with the step-like extension of the housing.

The height of the terminal plate may be greater than twice the predetermined wire gauge. The height may be less than three or four times the predetermined wire gauge. This allows for multiple wires to be inserted into one terminal. In particular, the multiple wires of a specific terminal, e.g. two or three wires, may be located one above the other or others in the height direction directly at the terminal plates.

Each of the terminal plates can be configured to be attached to at least one wire of the electric cable.

Each terminal plate may be configured to be welded and/or soldered to the at least one wire. The at least one wire may be inserted and welded or soldered to one or two terminal plates of one terminal in a space between the two terminal plates of the one terminal of the plurality of terminals. Other means for attachment of the at least one wire to a terminal plate may also be provided, such as clinching, crimping and/or clipping.

Each terminal may be configured to be attached to two or more wires. This can reduce the complexity in wiring and installing and improve the performance of the connected devices.

To enhance the properties of the terminal, such as a higher corrosion resistance, each terminal may comprise a coating or plating with an arbitrary thickness made from, for example, gold or silver. The wires and, respectively, the mating contacts of the mating connector, may comprise the same plating made from the same material, at least in sections and in particular in sections that are connected to the terminal. In another embodiment, the plating of the components to be connected to the terminal may be made from a different material than the terminals and/or comprise a layer of plating with a different thickness than the terminals. For example, the terminals may be made from silver while the mating component of the mating connector and/or the wires or part of the wires may be made from gold and vice versa.

Each terminal of the plurality of terminals may comprise a mating portion. The mating portion may be configured to contact a mating contact of the mating connector. The mating portion may extend in the mating direction towards the mating connector. In other words, the mating portion may be at the front of a terminal, which front faces in the mating direction. In an embodiment, the mating portion may be monolithic with the terminal plate.

The mating portion may be formed by a mating plate. The mating plate may be coplanar with the terminal plate. In an embodiment, the mating plate may have a smaller height than the terminal plate along the height direction.

The distance between immediately adjacent terminal plates of two different adjacent terminals of the plurality of terminals, especially along the pitch direction, may be smaller than the distance between the terminal plates of any one of the two adjacent terminals in the pitch direction. That means that the space between the two terminal plates of one terminal along the pitch direction may be larger than the distance or pitch between two adjacent terminals along the pitch direction. The distance between two adjacent terminals along the pitch direction may be smaller than the distance between two terminal plates of one terminal along the pitch direction. The wall between the terminals formed by the housing may have a smaller width in pitch direction than the pitch of the terminals.

The connector assembly, especially the housing, may comprise a wire side, which can be the side of the housing where the wires can be attached to the plurality of terminals. Opposite from the wire side, the connector assembly may further comprise a mating side with a mating side pitch direction, defining the direction of the pitch between the mating portions of the connector assembly facing the mating connector. This mating side pitch direction may be parallel or the same as the wire side pitch direction. In another embodiment, the mating side pitch direction may have an angle with respect to the wire side pitch direction, for example a 90 degree angle.

The connector assembly may further comprise a plurality of conductors to be connected to the plurality of terminals. The connector assembly may comprise a plurality of electric wires. Each of the electric wires may have a predetermined wire gauge. The predetermined wire gauge may be the same for each wire. In an embodiment, each wire may have a different wire gauge.

Two wires of the plurality of electric wires may be connected to one terminal of the plurality of terminals. The plurality of wires may come in pairs of two wires, i.e. comprise an even number of wires. Each pair of wires may be connected to each terminal of the plurality of terminals. If, at each terminal, n wires are attached, the plurality of electric wires may be an integer multiple of n.

Attaching more than one wire to a terminal allows for an increase of the current and, at the same time, the use of a small wire gauge, because a plurality of wires has an increased conductive cross-section compared to a single wire.

The two wires of the pair of wires may be connected to different terminal plates of one terminal, to each terminal plate of one terminal respectively, or they may be connected to the same terminal plate of the one terminal. In another embodiment, the two wires may also be connected to both terminal plates of one terminal.

The two wires that are connected to the one terminal may be spaced apart from one another in the height direction.

Two additional wires may be connected to a terminal adjacent to a terminal that is already connected to two wires. The two additional wires may be shifted in the height direction relative to the two wires of the one terminal. In particular, one of the two additional wires may be located between two of the wires of the adjacent terminal along the height direction. The wires may be shifted in a way that two wires that are directly adjacent to each other along the pitch direction are not lined up or aligned along the same line, for example along the pitch direction.

The plurality of wires may be arranged in a staggered arrangement when they are connected to the terminal plates. The staggered arrangement defines that the two wires may be placed in one terminal in an offset to one or more wires that are inserted in the terminals adjacent to the one terminal in the pitch direction. In other words, the two wires in the terminals may be placed out of line of the pair of wires placed in the terminals adjacent to the left and to the right to the one terminal. The wires of the plurality of wires may be alternating between two different heights or placements or positions along a height direction, so they do not touch each other when mounted, welded or soldered to the terminals.

In the staggered or offset arrangement of the wires, the wires or pair of wires of adjacent terminals in pitch direction should not touch each other. In the staggered arrangement, each wire, inserted into a terminal directly next to an adjacent terminal with one or more wires, is inserted on a different height along the height direction than the one or more already inserted wires of the adjacent terminal or terminals. The next pair of wires further along the pitch direction next to the terminal with wires on a different height along the height direction may be arranged on the exact same height as the first terminal or the terminal before the last terminal with the pair of wires inserted. This ensures a regular offset or zigzag arrangement of the wires or the plurality of wires. The offset of the wires may be consistent, which means that each wire is shifted by the same amount along the height direction to create a repeating pattern.

The wires or at least the connected sections of each wire, where the wire is connected to the respective terminal of the plurality of terminals, may be arranged in multiple rows. The wires may, for example, be arranged in four rows. Each of the rows may be spaced apart from the adjacent row in the height direction, and the wires of each of the rows may be located between the wires of the adjacent row in the pitch direction.

The staggered arrangement or the zigzag arrangement may comprise at least four rows of wires. Each row may be in the same plane parallel to the height direction. Each row may comprise at least three wires.

To connect the wires to each terminal, each wire may comprise a wire tab that extends between the terminal plates of a terminal, especially between the two terminal plates of a terminal or the space between the two terminal plates of a terminal along the mating direction. The wire tab may be crimped, welded, or soldered to the wire. The wire tab itself may be welded or soldered to the terminal, in particular to one or two terminal plates of the terminal.

To ensure that the terminals are kept within the housing, the plurality of terminals may be held within the terminal receptacles by at least one retainer.

The retainer may be inserted along a direction perpendicular to the mating direction into the housing against the height direction. The retainer may be cuboidal and may comprise an extrusion with a retainer nose. The extrusion may protrude parallel to the height direction. The retainer nose may be located at the end of the extrusion and may extend along the mating direction.

The retainer nose may abut a retainer stop within the housing. The retainer stop may be arranged within at least one of the terminal receptacles of the plurality of terminal receptacles and may be located in the space between the two terminal plates of a terminal. The interaction of retainer stop and retainer nose prevents the retainer to be moved along the height direction.

The retainer can be made out of an electrically conductive material to connect the two terminal plates together and may establish an electrical connection between the two terminal plates.

In another embodiment, the retainer may also be made from an insulating material, for example, the same material as the housing. The terminal plates may then be separated by the retainer and only be connected via the wire tab that is welded to one or both terminal plates.

A terminal may comprise two retainers that retain the terminal or the terminal plates from two opposite sides. For example, each retainer may be inserted from two opposite directions of the housing, parallel to the height direction.

To enable the insertion of the at least one retainer, the housing may have at least one retainer recess to insert the retainer.

The housing may taper towards the mating connector and mating direction. The terminal, especially the terminal plates, may each taper towards the mating connector and mating direction.

The connector assembly may have a smaller height along the height direction on one end or side of the connector assembly, the mating side or end facing the mating connector, than on the other side, for example the wire side. The housing may comprise a smaller connector face at the end facing the mating connector than the height of the housing or the wire connector facing the wire side of the housing.

To ease the installation of the connector assembly, the housing may comprise a locking mechanism to lock the connector assembly to a mating component, for example an installation rack or a mating connector. The locking mechanism may comprise a protrusion that locks with the mating component. This ensures ease of use and a snap-to-lock locking mechanism. The protrusions may be held by arms that protrude from a surface of the housing or may protrude directly from a surface of the housing.

The locking mechanism may further comprise a front stop to prevent pushing the connector assembly too far into the mating component, like the installation rack. The front stop may protrude from a surface of the housing. The front stop may protrude from the same surface of the housing as the protrusions.

The locking mechanism may be arranged on the surface of the housing and may protrude from, for example, two opposite surfaces of the housing, i.e. two opposite narrow surfaces of the housing or one or both surfaces facing the height direction.

The housing may comprise at least one ventilation hole for each of the terminal receptacles of the plurality of terminal receptacles. The ventilation hole may take the form of a polygon and be rectangular, for example. The ventilation holes may be arranged on the wire side or near the wire side of the housing facing the wires or on the mating side or near the mating side of the housing facing the mating connector. The ventilation holes may face the height direction. In one embodiment, the ventilation holes may be arranged close the each connector face of the connector assembly, the one connector face on the wire side and the connector face on the mating side of the connector assembly. In another embodiment, the ventilation holes may be arranged on both sides or near both sides of the housing.

The mating connector for mating with a connector assembly may be configured to be mated to a PCB. The mating connector may comprise a PCB side with PCB pins protruding towards the PCB that are to be mated or soldered onto the PCB. The PCB pins may protrude along a direction parallel to the height direction, away from the mating connector.

The mating connector may comprise mating contacts. The mating contacts may comprise contact members protruding towards the connector assembly along the mating direction. The mating members may be elastically deflectable and may be located in the space between two terminal plates when mating. Each contact member may push outward against each terminal plate to establish and keep an electrical connection with the connector assembly.

The mating connector may further comprise at least one guiding recess to guide at least one guiding pin of the connector assembly while mating. The at least one guiding pin of the connector assembly may protrude in the mating direction towards the mating connector and may be inserted into the at least one guiding recess.

On the side of the mating connector not facing the connector assembly, the mating connector may comprise protrusions between the two mating contact plates to mate with another connector with only one plate or conductor, for example.

The invention shall be explained in more detail hereafter by way of example with reference to the drawings. The feature combinations illustrated in the embodiments shown by way of example can be supplemented by further features in accordance with the above statements in correspondence with the properties of the invention required for a specific application. Individual features can also be omitted in accordance with the above statements from the embodiments described if the effect of these features is of no relevance for a specific application. The same reference numerals in the drawings are always used for elements having the same function and/or the same structure.

### BRIEF DESCRIPTION OF THE DRAWINGS

FIG. 1 is a perspective view of a connector assembly according to an embodiment.

FIG. 2 is an exploded view of a connector assembly according to an embodiment with wires and retainers.

FIG. 3 is a perspective view of a connector assembly according to an embodiment with wires.

FIG. 4 is a perspective view of a connector assembly according to an embodiment with wires and the rows depicted.

FIG. 5 is a perspective view of a connector assembly according to an embodiment.

FIG. 6 is a sectional view of the connector assembly according to an embodiment.

FIG. 7 is an exploded view of the connector assembly according to an embodiment with a mating connector.

FIG. 8 is a perspective view of the connector assembly according to an embodiment, with an electric cable and mounted to a mating component.

FIG. 9 is a perspective side view of the connector assembly installed on a mating component according to an embodiment.

FIG. 10 is a perspective view of an electric connector with a connector assembly according to an embodiment and a mating connector according to an embodiment.

FIG. 11 is a sectional view of the connector assembly mated with a mating connector according to an embodiment.

FIG. 12 is a sectional view of the mating connector according to an embodiment.

### DETAILED DESCRIPTION OF THE INVENTION

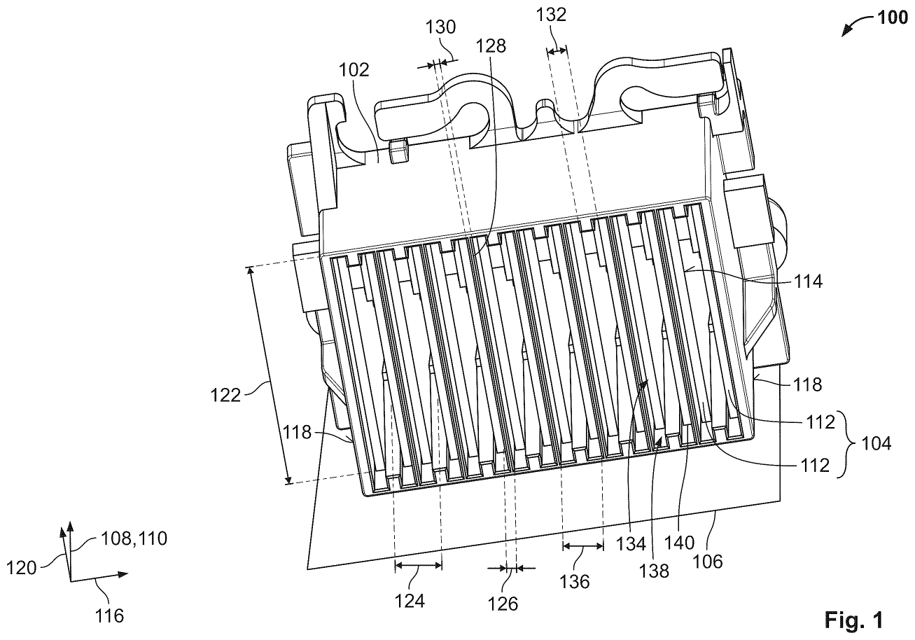

A connector assembly 100 according to an embodiment as shown in FIG. 1 comprises a housing 102, and a terminal 104, which is part of a plurality of terminals.

The terminal 104 is arranged or standing on a common terminal plane 106, on which the plurality of terminals is arranged. The common terminal plane 106 extends parallel to an insertion direction 108, which may be the same as the mating direction 110. The insertion direction 108 may describe the direction in which the terminal 104 or the plurality of terminals is inserted into the housing 102.

The terminal 104 may comprise two terminal plates 112. The terminal plates 112 may extend along the insertion direction 108 or the mating direction 110.

The terminal plates 112 of a terminal 104 may be parallel to each other, which means that the terminal plates 112 may be aligned in such a way that the two terminal plates 112 maintain a constant distance between each other, especially between the flat surfaces 114 of the terminal plates 112. The flat surfaces 114 of the terminal plates 112 may face a direction perpendicular to the insertion direction 108. The pitch direction 116 may extend from one narrow surface 118 to the opposite surface 118 of the housing 102.

Perpendicular to the pitch direction 116 and the insertion direction 108 or the mating direction 110, the terminal plate 112 may extend along a third direction 120, a height direction, defining a height 122 of the terminal plate 112.

The terminal 104 may be spaced from the adjacent terminal 104 by a distance 124 along the pitch direction 116. This distance 124 may also be defined as the pitch 124 of the terminals, or the plurality of terminals.

The pitch 124 may be greater than a distance 126 between two adjacent terminal plates 112 of two different terminals 104, at least along the pitch direction 116. The housing 102 may comprise a wall 108 that extends along the flat surfaces 114 of the terminal plates 112 and may separate two terminals 104 that are adjacent to each other from one another.

The distance 126 between two terminal plates 112 of two adjacent terminals 104 may be the same as the thickness 130 of the wall between the two different terminals 104 along the pitch direction 116.

The distance 126 between the two terminal plates 112 of two different terminals 104, or the thickness of the wall 130, may be smaller than a distance 132 between two terminal plates 112 of one terminal 104 along the pitch direction 116. The distance 132 may be between two terminal plates of the same terminal.

The terminal 104 may be located in a receptacle 134 of the housing 102.

The receptacle 134 may be part of a plurality of receptacles arranged along the pitch direction 116 to receive each of the terminals 104 of the plurality of terminals.

The width 136 of the receptacle may equal the distance 132 between two terminal plates 112 of the same terminal 104 along the pitch direction 116.

The housing 102 may have a box shape and be cuboidal. The width of the housing may extend along the pitch direction. The height of the housing may extend along the height direction and the length of the housing 102 may extend along the mating direction 110 or the insertion direction 108.

The receptacle 134 may comprise grooves 138 extending along the insertion direction 108, which are configured to receive a terminal plate 112 and to prevent moving in the pitch direction 116.

The groove 138 may be formed on only one side or one end 140 of the terminal plate 112. In another embodiment, the groove may be formed on both ends of the terminal plate 112 along the height direction 120.

The groove 138 and the receptacle 134 may extend just as far as or further than the terminal plate 112 into the housing 102.

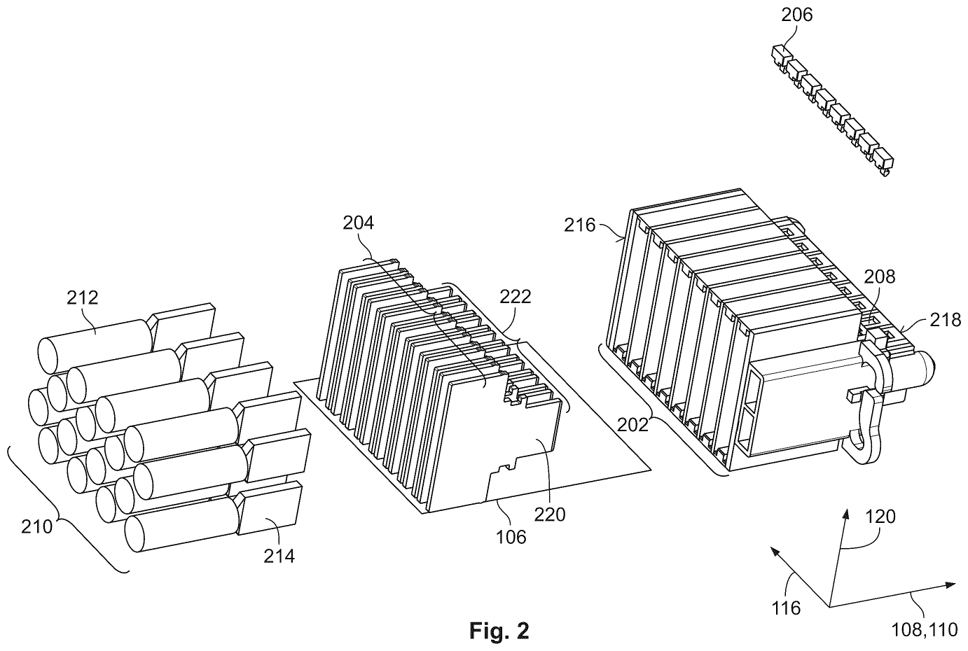

FIG. 2 shows the connector assembly 100 with the housing 102. The housing may comprise a plurality of receptacles 202, which are arranged next to each other along the pitch direction 116.

The plurality of receptacles 202 may be configured to receive a plurality of terminals 204 arranged on a common terminal plane 106.

The plurality of terminals 204 may be held within the housing 102 with at least one retainer 206.

The retainer 206 may be inserted in a direction opposite the height direction 120 into the housing 102. The housing may comprise at least one retainer recess 208 to receive at least one retainer 206. The retainer 206 may be configured to hold one or more terminal plates 112 of the plurality of terminals 204.

The retainers 206 may be located on two opposite sides or opposite ends of the terminal plates 112 just like the groove 138.

The plurality of terminals 204 may receive a plurality of wires 210 along the insertion direction 108.

Each wire 212 may comprise a wire tab 214 that may be attached by e.g. welding, soldering or crimping.

Each wire tab 214 may be inserted into one terminal 104 of the plurality of terminals 204 between two terminal plates 112 of one terminal 104.

The wire 212 or the wire tab 214 may be welded to at least one terminal plate 112 or to both terminal plates 112 of a terminal. The connector assembly 100 may comprise a wire side 216 which is the side of the housing 102 on which the wires 212 may be inserted.

The connector assembly 100 may further comprise a mating side 218, on which the connector assembly 100 may be mated to a mating connector.

For that purpose, the connector assembly 100 may comprise a mating portion 220, which may be part of a plurality of mating portions 222 which extends along the mating direction 110 as well as along the height direction 120 just as the terminal plates 112. The mating portion 220 or the plurality of mating portions 222 may be part of the terminal plate 112, making a monolithic design or a monolithic part comprising a terminal plate and a mating portion on two different ends.

The terminal plate 112 may be located on the wire side 216 and the mating portion 220 may be located on the mating side 218 of the connector assembly 100.

The mating portion 220 may be accessible from outside the housing by a mating connector.

The terminal 104 may be accessible from at least the wire side 216 in the insertion direction 108 to connect to a wire 216 or a wire tab 214.

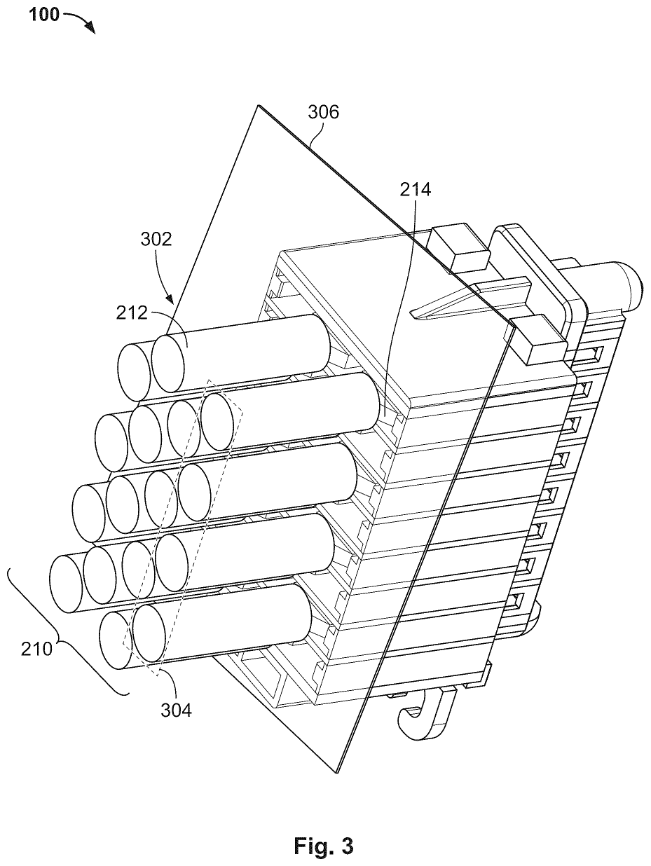

FIG. 3 shows the connector assembly 100 where the wires 212 are connected to the terminals 104 via the wire tabs 214.

When inserted, the wires 212 or the plurality of wires 210 may be arranged in a staggered arrangement 302 when connected to the terminal plates 112.

Two wires 212 may be placed in the terminal 104 in an offset to one or more wires 214 in the terminal 104 adjacent to them. The wires or the plurality of wires 210 may form rows 304 which are arranged on the same plane 306 which is parallel to the height direction.

The rows 304 may be formed along the height direction 120. Each row 304 may comprise two or more wires 212, e.g. as shown, four wires 212.

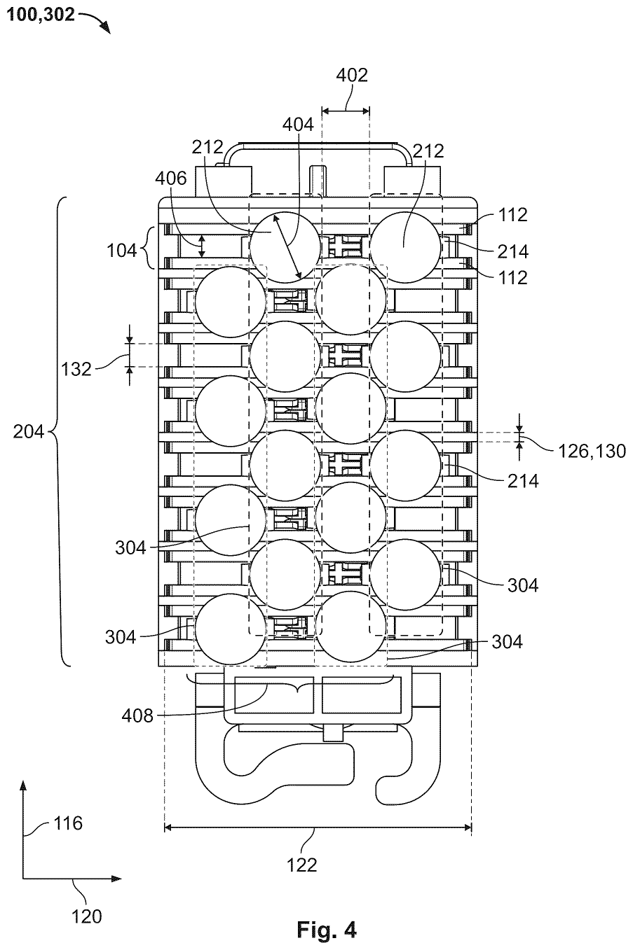

FIG. 4 shows the connector assembly 100 with four rows 304 of wires along the height direction 120.

Each terminal 104 is connected to two wires 212 wherein the two wires comprise a distance 402 along the height direction 120. The distance 402 may be smaller than a wire gauge 404 of each wire 212. The plurality of wires may comprise the same wire gauge 404. The wire gauge 404 may be greater than the distance 132 between the two terminal plates of the same terminal 104 along the pitch direction 116.

The wire tab 214 of each wire 212 may be inserted into the space 406 between the two terminal plates 112 of a terminal 104.

The height 122 of each terminal 104 may be greater than twice the wire gauge 404. In one embodiment, the height 122 of the terminal plate 112 may be three or four times greater than the wire gauge 404. The rows 304 may be alternating along the pitch direction 116. The distance 402 between the wires 212 along the height direction 120 may equal the wire gauge 404 of the wire 212 inserted into the terminal 104 next to the two wires. In another embodiment the distance 402 may be smaller than the wire gauge 404 while still maintaining that two adjacent wires 212 along the pitch direction 116 do not touch each other.

The rows 304 may overlap in the height direction 120 without the wires 212 of adjacent terminals 104 touching each other. Each terminal 104 may have two wires 212 that comprise the same distance 402 between each other along the height direction 120 for a more uniform arrangement. In another embodiment, the placement of the wires is arbitrary, as long as the wires 212 do not touch the wires 212 of the adjacent terminals 104. The distance 402 between the wires 212 may thus vary for each terminal 104 of the plurality of terminals 204.

Each terminal 104 may be connected to one or two wires 212 or a pair of wires 408. Each pair of wires 408 may comprise the same placement as the pair of wires 408 in the terminal after the next or the second next terminal 104 to achieve a regular zigzag arrangement or repeatable offset arrangement or staggered arrangement 302.

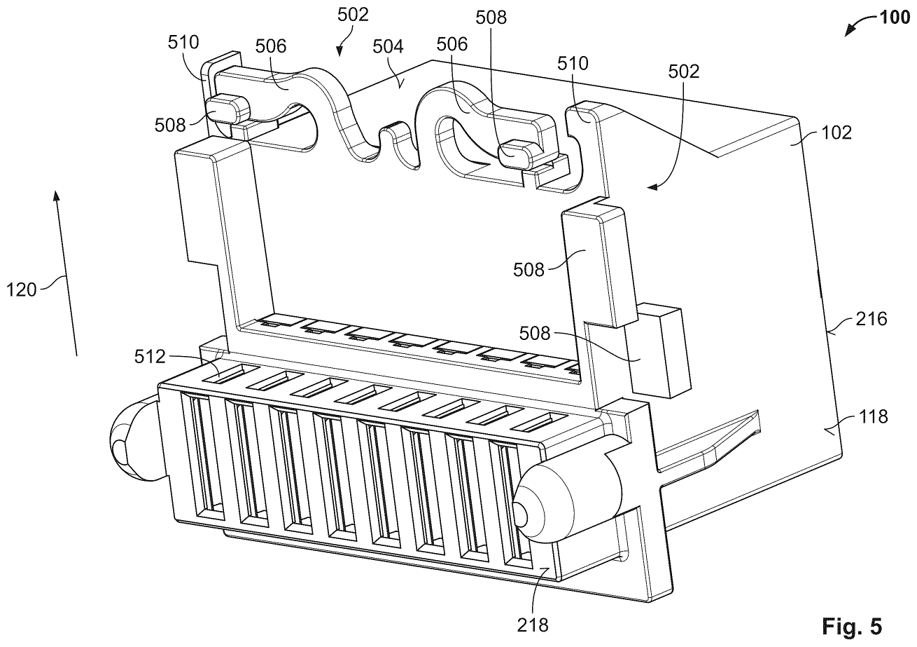

FIG. 5 shows an embodiment of the connector assembly 100. The connector assembly 100 may comprise a locking mechanism 502. The locking mechanism 502 may comprise sections that protrude from a surface or at least a surface 504 of the housing 102, for example, on the surface 504 facing the height direction 120, wherein the locking mechanism 502 extends along the height direction 120. Another embodiment of the locking mechanism 502 comprises parts of the locking mechanism 502 protruding from one or more narrow surfaces 118 of the housing 102.

The locking mechanism 502 may be configured to lock the connector assembly 100 to a mating component, for example an installation rack that has a recess for the connector to be installed on. The locking mechanism 502 may comprise arms 506 holding protrusions 508 that may lock the connector assembly to a mating component, for example the installation rack.

The housing 102 may comprise more protrusions 508 that hold the connector assembly 100 to the installation rack by holding the installation rack between two protrusions 508.

The locking mechanism 502 may be configured to enable pushing the connector assembly 100 onto an installation rack and locking the connector assembly 100 immediately. For this purpose the locking mechanism 502 may comprise front stoppers 510 that prevent the user from pushing the connector assembly too far.

The connector assembly 100 may further comprise ventilation holes 512. These contribute to a better heat management during an electrical connection.

The ventilation holes 512 may be located on a surface 504 of the housing facing the height direction 120, allowing for ventilation by convection. Each terminal 104 or each receptacle 134 may comprise at least one ventilation hole 512.

The ventilation holes 512 may be arranged closer to the mating side 218 of the connector assembly 100. Alternatively or cumulatively the ventilation holes 512 may be arranged on the wire side 216 or closer to the wire side 216 of the connector assembly and can be adjusted according to the needs.

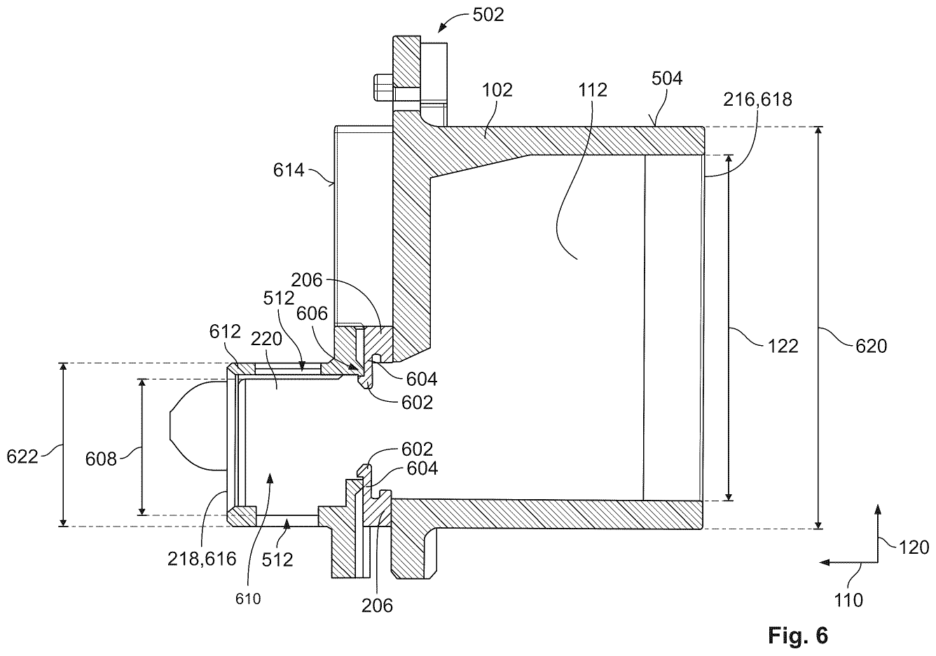

FIG. 6 shows a sectional view of an embodiment of the connector assembly 100. The connector assembly 100 is cut along a plane spanned by the height direction 120 and the mating direction 110.

The terminal plate 112 shown comprises the height 122 on the wire side 216 of the connector assembly 100. The terminal plate 112 may taper along the mating direction 110 within the housing 102. The housing 102 may taper similar to the terminal plate 112 or the plurality of terminals 204.

The flat surface 114 of the terminal plate extends along a plane parallel to the plane of the sectional cut along the height direction 120 and the mating direction 110.

The terminal plates 112 of the terminal 104 are held within the housing 102 with retainers 206. In this embodiment, there is one retainer 206 on two opposite sides of the housing 102. One retainer may be inserted along the height direction 120, the other may be inserted against the height direction 120 into respective retainer recesses 208.

Each retainer may comprise a retainer nose 602 protruding in the mating direction 110. The retainer nose 602 may be attached to an extrusion 604 of the retainer 206 which extends along the height direction 120. This extrusion 604 may be configured to be elastically deflectable in the mating direction 110 or against the mating direction 110.

The connector housing 102 may further comprise a stop 606, the stop 606 may protrude towards the retainer 206 against the mating direction 110 and abut the retainer nose 602 to prevent the retainer 206 to be moved out of the housing 102 in the height direction 120 or against the height direction 120. The retainer 206 may further abut one or more, for example two, terminal plates 112 to hold the terminal 104 securely in the housing 102.

The connector assembly 100 in the embodiment of FIG. 6 comprises a mating portion 220 that has a mating portion height 608 along the height direction 120. The mating portion height 608 may be smaller than the height 122 of the terminal plate 112. The height 122 of the terminal plate 112 may be more than twice as large as the mating portion height 608 in the height direction 120.

The terminal plate 112 and the mating portion 220 may be connected in another embodiment. The mating portion 220 may be at a front 609 of the terminal 104 or terminal plate 112. The front 610 may face the mating connector. The mating portion 220 and the terminal plate 112 of a terminal 104 may be made of the same material and made out of the same part, making this a monolithic design to reduce the number of parts to be assembled.

In this embodiment, the connector assembly comprises a step-like extension 612 protruding from a face 614 of the housing. The step-like extension 612 may protrude in the mating direction 110 and may comprise a mating-side connector face 616 that is facing the mating connector. On the other side, the wire side 216, the housing may comprise a wire-side connector face 618 facing the wires 212. The height 620 of the wire-side connector face 618 may be greater than the height 622 of the mating-side connector face 616.

The connector assembly may further comprise ventilation holes 512 on two opposite sides along the height direction 120 on the mating side 218 of the connector assembly. In another embodiment, the connector assembly may alternatively or cumulatively comprise ventilation holes 512 on the wire side 216 as well, for example on the surface 504 of the housing.

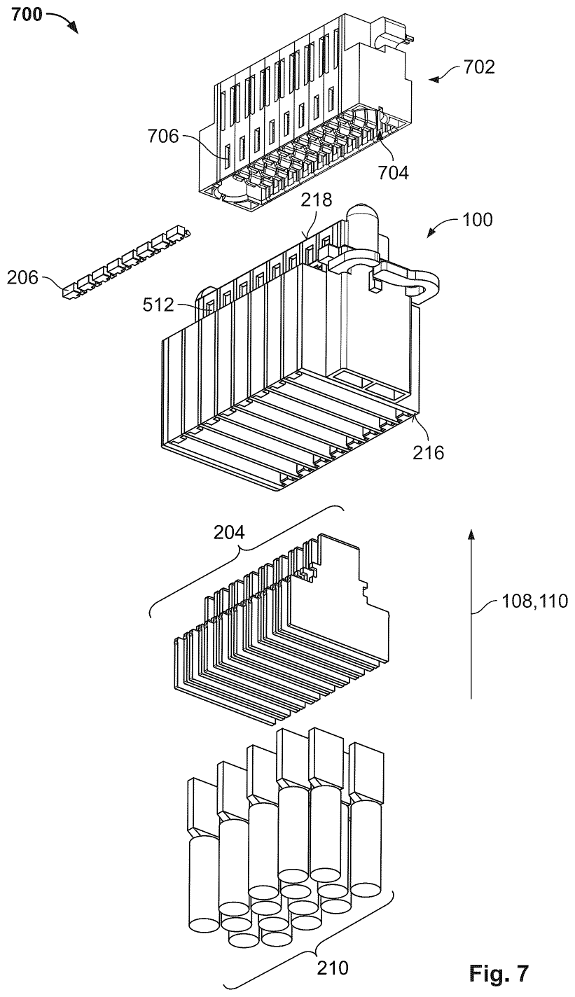

FIG. 7 shows an exploded view of the connector assembly 100 and the electrical connector 700 with the mating connector 702 that may mate to the connector assembly 100. The mating connector 702 may be mated to the connector assembly 100 on the mating side 218 of the connector assembly. On the wire side 216, the plurality of terminals 204 as well as the plurality of wires 210 may be inserted in the insertion direction 108 or the mating direction 110.

The connector assembly may comprise a staggered arrangement 302 of the plurality of wires 210.

The mating connector 702 may comprise a mating contact 704 protruding towards the connector assembly 100 against the mating direction 110. The mating connector 702 may further comprise ventilation holes 706.

The electrical connector 700 may comprise the mating connector 702, but may also comprise only the connector assembly 100.

Each terminal of the plurality of terminals 204 may be plated with a material of arbitrary thickness for example, gold or silver. The plurality of wires 210 and, respectively, the mating contacts 704 of the mating connector 702, may be plated with the same material, at least in sections and in particular in the sections connected to the terminal, i.e. on the mating side 218 and/or the wire side 216. In another embodiment, the components to be connected to the each of the plurality of terminals 204, for example the mating contacts 704 and/or the plurality of wires 210 may be plated with a different material than the terminals 202. For example, the terminals 202 may be made from silver while the mating contacts 704 of the mating connector 702 and/or the wires 212 or part of the wires 212 may be made from gold and vice versa.

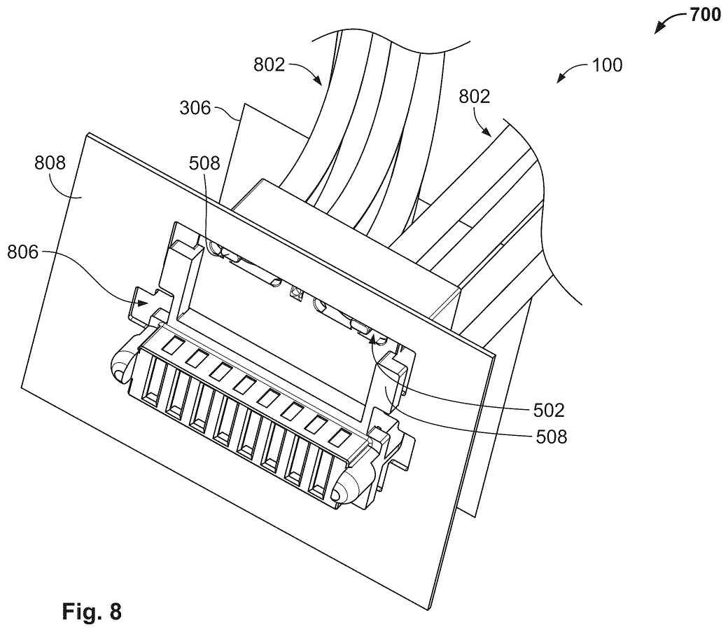

FIG. 8 shows the electrical connector 700 with the connector assembly 100, whereas the plurality of wires 210 are part of an electric cable 802. The plurality of wires 210 is arranged on the wire plane 306 in a staggered or zigzag arrangement along the plane 306. The connector assembly 100 may be pushed into a mating component 804. In this example, the connector assembly 100 may be pushed into a recess 808 of an installation rack 808. The locking mechanism 502 of the connector assembly 100 secures the connector assembly within the installation rack. The protrusions 508 block the movement of the connector assembly 100.

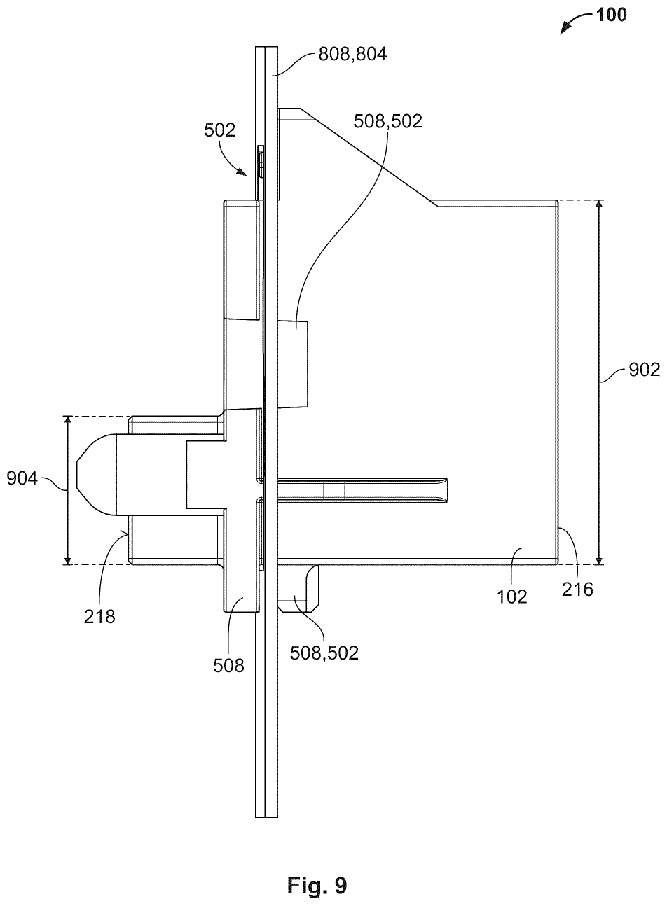

FIG. 9 shows a perspective side view of the connector assembly 100 mounted on an installation rack 808 or a similar mating component 804. The protrusions 508 of the locking mechanism 502 securely hold the connector assembly to the installation rack 808. The housing 102 in this embodiment has a different height 902 on the wire side 216 than the height 904 of the housing 102 on the mating side 218 of the housing 102.

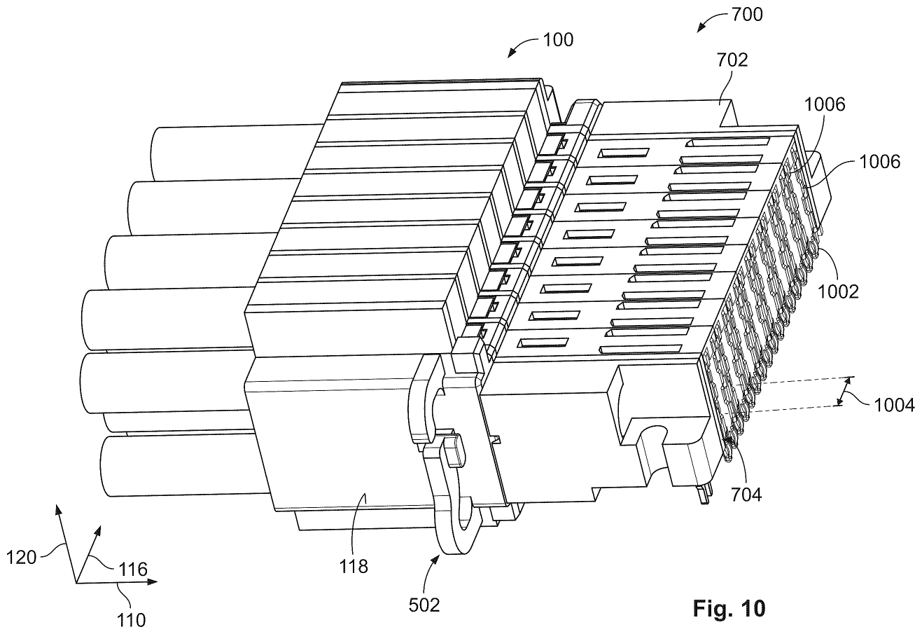

FIG. 10 shows the electrical connector 700 with a mating connector 702 and a connector assembly 100 mated to each other. In this embodiment, the mating connector 702 comprises PCB pins 1002. The PCB pins 1002 may be configured to be mated to a PCB.

The mating connector 702 may comprise a mating pitch 1004 between each mating contact 704. The mating pitch 1004 may be the same as the pitch 124 of the connector housing.

The mating contact 704 of the terminal connector may each also comprise two contact plates 1006. They may also be arranged on the terminal plane 106 and extend parallel to the height direction 120. They may face the pitch direction 116 just as the terminal plates 112 of the connector assembly 100.

This embodiment shows a locking mechanism of the connector assembly that protrudes from one of the narrow surfaces 118 of the housing.

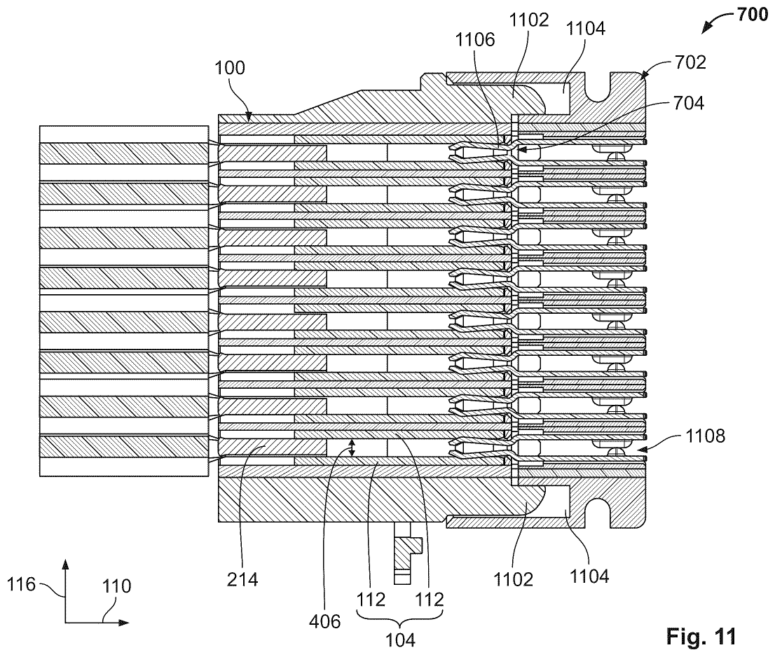

FIG. 11 shows an electrical connector 700 with a mating connector 702 and the connector assembly 100 mated to each other. The sectional view in FIG. 11 depicts guiding pins 1102 on the connector assembly 100. They may protrude in the mating direction 110 towards the mating connector 702. When mating, they may be inserted into guiding recesses 1104 formed in the mating connector 702 to guide the connector assembly 100 while mating.

The sectional view shows how the wire tabs 214 are located in the space 406 between two terminal plates 112 of one terminal 104.

The mating contacts 704 of the mating connector 702 may comprise contact members 1106 on each contact plate 1002. The two contact members 1106 of the mating contact 704 may protrude against the mating direction 110 towards the connector assembly 100 and may be located in the space 406 between the terminal plates 112 of the connector assembly 100. When mating, the contact members 1106 may be configured to push outwards against the two terminal plates 112 within a terminal 104. When mating, the contact members 1106 may be springs or elastically deflectable to hold the mating connector 702 in place.

The mating connector 702 may further comprise terminal holders 1108 that protrude in the pitch direction 1106 and enable a secure mating of a single terminal, for example.

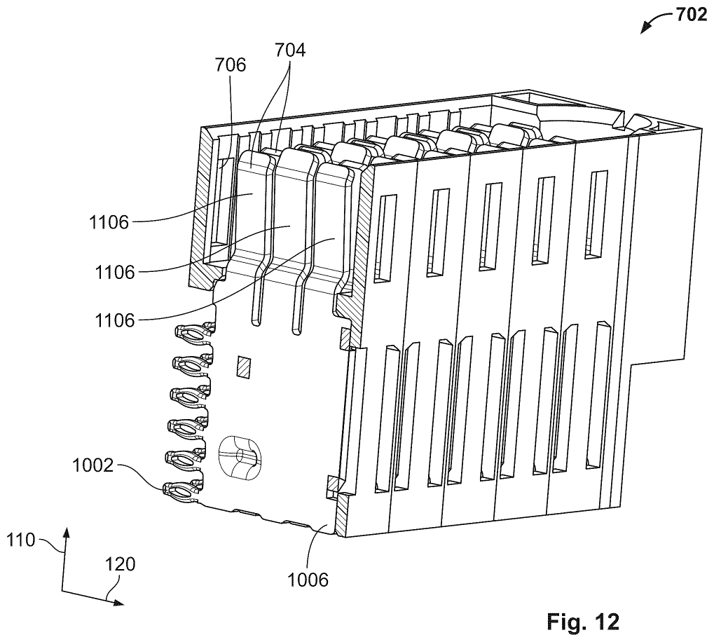

FIG. 12 shows a sectional view of the mating connector 702.

The mating contact 704 comprises two contact plates 1006. Each contact plate comprises PCB pins 1002 protruding against the height direction 120.

The mating connector 702 comprises three contact members on each contact plate 1006. The contact members 1106 protrude against the mating direction 110 and may converge each other slightly.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

What is claimed is:

1. Connector assembly for electric cables having a predetermined wire gauge to be mated with a mating connector along a mating direction, the connector assembly comprising:
a plurality of terminals that is arranged on a common terminal plane, the common terminal plane extending parallel to the mating direction;
wherein each of the terminals is configured to be connected to at least one wire,
the distances between each of the plurality of terminals in a pitch direction being smaller than the predetermined wire gauge.

2. Connector assembly according to claim 1, wherein each terminal is configured to be attached to two wires.

3. Connector assembly according to claim 1, wherein
the connector assembly comprises a housing with a plurality of terminal receptacles, wherein
each terminal of the plurality of terminals comprises two terminal plates arranged parallel to one another within one terminal receptacle of the plurality of terminal receptacles, each of the terminal plates being configured to attach to at least one wire of the electric cable.

4. Connector assembly according to claim 3, wherein
each terminal of the plurality of terminals is received in a different terminal receptacle of the plurality of terminal receptacles.

5. Connector assembly according to claim 3, wherein each terminal of the plurality of terminals comprises a mating portion that is configured to contact a mating contact of the mating connector, the mating portion being monolithic with the terminal plate.

6. Connector assembly according to claim 3, wherein the distance between immediately adjacent terminal plates of two adjacent terminals of the plurality of terminals is smaller than the distance between the terminal plates of any one of the two adjacent terminals.

7. Connector assembly according to claim 3, wherein the housing comprises at least one ventilation hole for each of the terminal receptacles of the plurality of terminal receptacles.

8. Connector assembly according to claim 1, wherein the connector assembly comprises a plurality of electric wires, each of the electric wires having a predetermined wire gauge, and wherein two wires of the plurality of electric wires are connected to one terminal of the plurality of terminals respectively.

9. Connector assembly according to claim 8, wherein the two wires are connected to different terminal plates or to the same terminal plate of the one terminal.

10. Connector assembly according to claim 8, wherein the two wires that are connected to the one terminal are spaced apart in the height direction.

11. Connector assembly according to claim 8, wherein two wires are connected to a terminal that is adjacent to the one terminal and are shifted in the height direction relative to the two wires of the one terminal.

12. Connector assembly according to claim 8, wherein the plurality of wires is arranged in a staggered arrangement.

13. Connector assembly according to claim 12, wherein the staggered arrangement comprises at least four rows of wires.

14. Connector assembly according to claim 8, wherein each wire comprises a wire tab that extends between the terminal plates of a terminal.

15. Electric connector comprising:
a connector assembly including a plurality of terminals that is arranged on a common terminal plane, the common terminal plane extending parallel to the mating direction, each of the terminals is configured to be connected to at least one wire, wherein the distances between each of the plurality of terminals in a pitch direction being smaller than the predetermined wire gauge; and
a mating connector comprising a plurality of mating contacts with a mating pitch that is equal to the distance of the terminals of the connector assembly.

16. Electric connector according to claim 15, wherein each terminal is configured to be attached to two wires.

17. Electric connector according to claim 15, wherein
the connector assembly comprises a housing with a plurality of terminal receptacles, wherein
each terminal of the plurality of terminals comprises two terminal plates arranged parallel to one another within one terminal receptacle of the plurality of terminal receptacles, each of the terminal plates being configured to attach to at least one wire of the electric cable.

18. Electric connector according to claim 17, wherein the distance between immediately adjacent terminal plates of two adjacent terminals of the plurality of terminals is smaller than the distance between the terminal plates of any one of the two adjacent terminals.

19. Electric connector according to claim 15, wherein the connector assembly comprises a plurality of electric wires, each of the electric wires having a predetermined wire gauge, and wherein two wires of the plurality of electric wires are connected to one terminal of the plurality of terminals respectively.

20. Electric connector according to claim 19, wherein the two wires that are connected to the one terminal are spaced apart in the height direction.
